(19) United States
(12) Patent Application Publication
(10) Pub. No.: US 2007/0241274 A1
(43) Pub. Date: Oct. 18, 2007

(54) METHOD FOR CALIBRATING EXPOSURE APPARATUSES OF DIFFERENT TYPES USING SINGLE MASK AND METHOD TO AUTO-FEEDBACK OPTIMUM FOCAL LENGTH

(76) Inventors: Ching-Hsiang Chang, Miaoli County (TW); Chien-Min Wu, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,896

(22) Filed: Sep. 27, 2005

(30) Foreign Application Priority Data
Jul. 19, 2005 (TW) 94124259

(51) Int. Cl. G01D 18/00; G03F 7/00

(52) U.S. Cl. 250/252.1; 430/5

(57) ABSTRACT

An apparatus-testing mask and a method for calibrating essential parameters of exposure apparatuses on the optics principle base are provided. The mask includes a light-transparent substrate and calibration patterns disposed on the light-transparent substrate. Wherein, each of the calibration patterns includes a recognition pattern having symmetricity, a comparison pattern disposed around the recognition pattern and two pairs of calibration reticles disposed around the comparison pattern and extending along four directions (for example, 0°, 45°, 90° and 135°), respectively. By using the mask to calibrate the exposure apparatuses, the uptime of the exposure apparatuses is enhanced, the masks used for calibration are unified and some essential parameters of an exposure apparatus, such as focal length, skew degree and phase error are able to be calibrated using an auto-feedback system.

### BACKGROUND OF THE INVENTION

1. Field of Invention

The present invention relates to a tool for calibrating apparatuses and the calibration method thereof, and particularly to a mask and a method for calibrating exposure apparatuses.

2. Description of the Related Art

Lithography is counted as one of the most important processes in the semiconductor manufacturing. The basic parameters related to the lithography process include exposure dose, alignment accuracy and focal length. Wherein, exposure dose and alignment accuracy can be evaluated by an off-line measurement apparatus, which is separated from a track machine. Namely, a photoresist pattern of a produced wafer is measured by the measurement apparatus to get a quantified result and other derived information, so that the process capability of the exposure apparatus is estimated. In addition, the above-described measurement result can serve to auto-feedback the exposure apparatus, wherein a qualify control (QC) technique, for example, an advanced process control (APC) is used to enable the exposure apparatus running controlled by the preferred parameters.

However, the focal length is different from exposure dose and alignment accuracy. In fact, the focal length is difficult to be estimated by a measurement apparatus through measuring the photoresist pattern. Therefore, in comparison with the exposure dose and alignment accuracy, the QC of a focal length has at least the following disadvantages.

1. A method for measuring focal length provided by an exposure apparatus builder requires the provided exposure apparatus itself to perform, and during measurement, the exposure apparatus is not able to serve for exposing in mass production of wafers, which leads to a less uptime.

2. Since a focal length is not able to be estimated by a measurement apparatus through measuring the photoresist pattern, the above-described auto-feedback system is not suitable for the QC of a focal length. As a replacement, a man-made, manual mode is employed for compensation. Wherein, a personal fault is unavoidable.

3. General speaking, when the production capability is an exposure apparatus is not sufficient to meet need, another apparatus would usually be allocated for a support task. At the moment, a focal length comparison job is needed between the supporting exposure apparatus and the supported exposure apparatus. However, for an exposure apparatus with a different builder or a different generation, a different mask is used as a datum for measuring focal length, not to mention the different measurement methods, so that the measurement results are not suitable for the comparison and an evaluation on the commutative usage exposure apparatus are difficult.

4. Normally, the method for measuring focal length provided by a builder (for example, Nikon Co.) is limited for a shot area to be measured each time., which is not suitable to obtain a batch measurement results of focal length. Wherein, so-called shot area means an exposed area on a wafer, where a single scan is conducted by a scanning-exposing exposure apparatus, i.e. by a scanner.

### SUMMARY OF THE INVENTION

An object of the present invention is to provide a mask suitable for calibrating focal lengths of various exposure apparatuses to unify the calibration datum of focal lengths for various exposure apparatuses.

Another object of the present invention is to provide a method for calibrating an exposure apparatus to advance the uptime thereof.

The present invention provides a mask suitable for calibrating an exposure apparatus. The mask includes a light-transparent substrate and at least two calibration patterns disposed on the light-transparent substrate. Each of the calibration patterns includes a symmetrical recognition pattern; a comparison pattern disposed around the recognition pattern; a first pair of calibration reticles disposed around the comparison pattern and extending along a first direction; a second pair of calibration reticles disposed around the comparison pattern and extending along a second direction.

The present invention further provides a mask suitable for calibrating an exposure apparatus. The mask includes a light-transparent substrate and at least two calibration patterns disposed on the light-transparent substrate. Each of the calibration patterns includes a symmetrical recognition pattern, a comparison pattern disposed around the recognition pattern, a first pair of calibration reticles disposed around the comparison pattern and extending along a first direction, a second pair of calibration reticles disposed around the comparison pattern and extending along a second direction, a third pair of calibration reticles disposed around the comparison pattern and extending along a third direction and a fourth pair of calibration reticles disposed around the comparison pattern and extending along a fourth direction.

According to the mask described in a preferred embodiment of the present invention, the recognition pattern herein is, for example, a square or an octagon. The area of the recognition pattern is at least 100μ² (micron square).

According to the mask described in a preferred embodiment of the present invention, the first pair of calibration reticles, the second pair of calibration reticles, the third pair of calibration reticles and the fourth pair of calibration reticles herein have a line-width of 0.1˜0.2μ (micron).

According to the mask described in a preferred embodiment of the present invention, the light-transparent substrate herein has 9 calibration patterns transversely arranged thereon in a first interval and longitudinally arranged thereon in a second interval.

According to the mask described in a preferred embodiment of the present invention, one of the recognition pattern and the comparison pattern herein is a light-transparent pattern, while another is a lighttight pattern.

According to the mask described in a preferred embodiment of the present invention, the width of the comparison pattern herein is at least 3μ (micron).

According to the method for calibrating an exposure apparatus described in a preferred embodiment of the present invention, the calibration patterns herein are counted as a first calibration set applied to the exposure apparatus, while a second calibration set applied to another exposure apparatus can be further disposed on the light-transparent substrate and the calibration patterns corresponding to the first calibration set and the second calibration set are disposed at different positions, respectively.

Since the mask used for calibration of the present invention is suitable for various exposure apparatuses, the focal length of each exposure apparatus can be consequently compared with the same datum, so that a reference is provided to decide whether the apparatuses can be commutatively used.

The present invention provides further a method for calibrating an exposure apparatus. The method includes providing a mask comprising a light-transparent substrate and at least two calibration patterns on the light-transparent substrate. Wherein, each of the calibration patterns includes a symmetrical recognition pattern, a comparison pattern disposed around the recognition pattern, a first pair of calibration reticles disposed around the comparison pattern and extending along a first direction, a second pair of calibration reticles disposed around the comparison pattern and extending along a second direction.

Using the mask, a lithography process is conducted on a tested wafer placed on the exposure apparatus, so that a plurality of lithography patterns corresponding to the calibration patterns are obtained, followed by measuring the total lengths of every lithography pattern at the first direction and the second direction using a tester, respectively, to obtain a plurality of measurement values. Further, the values are compared with the values obtained from the total lengths at the first direction and the second direction of the calibration patterns. Afterwards, the obtained comparison result is used for calibrating the exposure apparatus.

The present invention provides further a method for calibrating an exposure apparatus. The method includes providing a mask comprising a light-transparent substrate and at least two calibration patterns on the light-transparent substrate. Wherein, each of the calibration patterns includes a symmetrical recognition pattern, a comparison pattern disposed around the recognition pattern, a comparison pattern disposed around the recognition pattern, a first pair of calibration reticles disposed around the comparison pattern and extending along a first direction, a second pair of calibration reticles disposed around the comparison pattern and extending along a second direction, a third pair of calibration reticles disposed around the comparison pattern and extending along a third direction and a fourth pair of calibration reticles disposed around the comparison pattern and extending along a fourth direction.

Using the mask, a lithography process is conducted on a tested wafer placed on the exposure apparatus, so that a plurality of lithography patterns corresponding to the calibration patterns are obtained, followed by measuring the total lengths of every lithography pattern at the first direction, the second direction, the third direction and the fourth direction using a tester, respectively, to obtain a plurality of measurement values. Further, the values are compared with the values obtained from the total lengths at the first direction, the second direction, the third direction and the fourth direction of the calibration patterns. Afterwards, the obtained comparison result is used for calibrating the exposure apparatus.

According to the method for calibrating an exposure apparatus described in a preferred embodiment of the present invention, wherein the tester is, for example, an off-line tester. The tester is, for example, a microscope.

According to the method for calibrating an exposure apparatus described in a preferred embodiment of the present invention, wherein a feedback mechanism is used for calibrating an exposure apparatus through the comparison result, which is auto-feedbacked to the exposure apparatus for calibrating.

According to the method for calibrating an exposure apparatus described in a preferred embodiment of the present invention, the recognition pattern herein is, for example, a square or an octagon. The area of the recognition pattern is at least 100μ² (micron square).

According to the method for calibrating an exposure apparatus described in a preferred embodiment of the present invention, the first pair of calibration reticles and the second pair of calibration reticles herein have a line-width of 0.1˜0.2μ (micron).

According to the method for calibrating an exposure apparatus described in a preferred embodiment of the present invention, the first pair of calibration reticles, the second pair of calibration reticles, the third pair of calibration reticles and the fourth pair of calibration reticles herein have a line-width of 0.1˜0.2μ (micron).

According to the method for calibrating an exposure apparatus described in a preferred embodiment of the present invention, the light-transparent substrate herein has 9 calibration patterns transversely arranged thereon in a first interval and longitudinally arranged thereon in a second interval.

According to the method for calibrating an exposure apparatus described in a preferred embodiment of the present invention, one of the recognition pattern and the comparison pattern herein is a light-transparent pattern, another is an opaque pattern.

According to the method for calibrating an exposure apparatus described in a preferred embodiment of the present invention, the width of the comparison pattern herein is at least 3μ (micron).

According to the method for calibrating an exposure apparatus described in a preferred embodiment of the present invention, the calibration patterns herein are counted as a first calibration set applied to the exposure apparatus, while a second calibration set applied to another exposure apparatus can be further disposed on the light-transparent substrate and the calibration patterns corresponding to the first calibration set and the second calibration set are disposed at different positions, respectively.

By using the method for calibrating an exposure apparatus in the present invention, an off-line tester is used to measure the wafer; therefore there is no need to bring the tested wafer back onto the exposure apparatus for measurement. In this way, the uptime of the exposure apparatus and the production capability are accordingly increased. On the other hands, the present invention uses the above-described feedback mechanism to give the exposure apparatus an auto-feedback for calibration, so that a personal fault caused by a man-made, manual calibration is avoided.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1 is a diagram of a mask in an embodiment of the present invention.

FIG. 2 is a diagram of the calibration pattern 102 of FIG. 1.

FIG. 3 is a diagram of the calibration pattern 103 in another embodiment of the present invention.

FIG. 4 is a step flowchart for calibrating an exposure apparatus according to an embodiment of the present invention.

FIG. 5 is a diagram of the lithography pattern 102a obtained by exposing the calibration pattern 102 of FIG. 2.

FIG. 6 is a diagram of the lithography pattern 103a obtained by exposing the calibration pattern 103 of FIG. 3.

### DESCRIPTION OF THE EMBODIMENTS

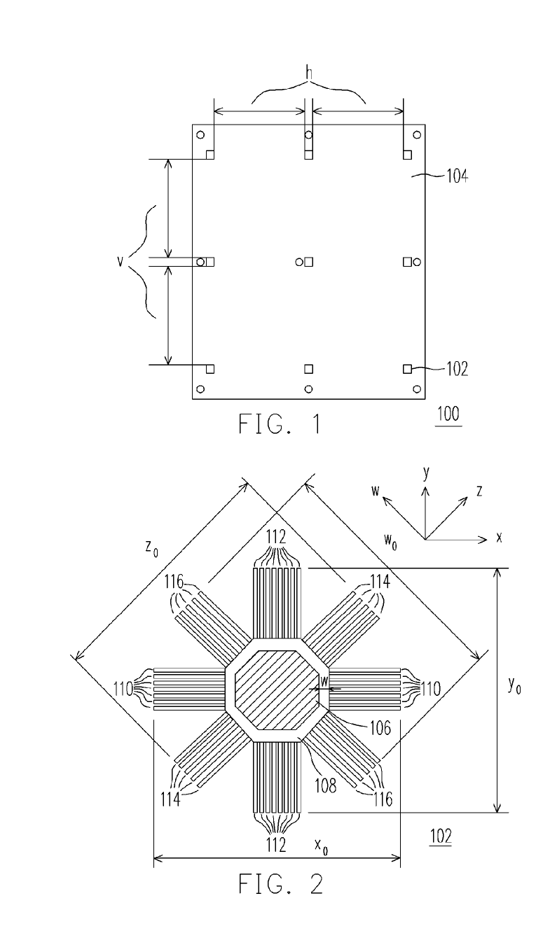

FIG. 1 is a diagram of a mask 100 in an embodiment of the present invention. The mask 100 is suitable for calibrating the focal length of an exposure apparatus and other focal length-related parameters. Wherein, the exposure apparatus is a step-and-scan and scanning-exposing exposure apparatus (scanner) provided by a manufacture, for example, Nikon Co., Canon Co. or ASML Co. In addition, FIG. 2 is a diagram of the calibration pattern 102 of a mask in FIG. 1.

Referring to FIG. 1 and FIG. 2, the mask 100 mainly includes a light-transparent substrate 104 and at least two calibration patterns 102 disposed on the light-transparent substrate 104. The calibration pattern 102 includes a recognition pattern 106, a comparison pattern 108, a first pair of calibration reticles 110, a second pair of calibration reticles 112, a third pair of calibration reticles 114 and a fourth pair of calibration reticles 116. In the embodiment, on the calibration pattern, four kinds of calibration reticles, but not limited to in the present invention, are disposed. For example, in comparison with the calibration pattern 102, the calibration pattern 103 in another embodiment of the present invention (FIG. 3) eliminates the third pair of calibration reticles 114 and a fourth pair of calibration reticles 116, only two pairs of calibration reticles are remained.

Wherein, for simplifying the design and fabrication of the mask, the recognition pattern 106 has a symmetrical feature. In particular, the symmetrical recognition pattern 106 is a preferred square or an octagon, or the other appropriate symmetrical patterns. In addition, considering that the mask 100 is used for calibrating the focal length of an exposure apparatus or the other focal length-related parameters, the recognition pattern 106 on the mask 100 must be size-sufficient. That is, the lithography patterns produced by the recognition pattern 106 on a wafer is free from deformation caused probably by an offset of no matter the focal length of an apparatus or the focal length-related parameters, so that the success rate of pattern recognition is enhanced. In a preferred embodiment, the area of the above-described recognition pattern is at least 100μ² (micron square).

The comparison pattern 108 is disposed around the recognition pattern 106, wherein the comparison pattern 108 has a width w. One of the recognition pattern 106 and the comparison pattern 108 is a light-transparent pattern, while another one is an opaque pattern, which provides a light and shade contrast between the recognition/pattern 106 and the comparison pattern 108 as an aid, so that an erroneous recognition can be significantly avoided and the success rate for the tester to recognize patterns is enhanced. On the other hand, the width w of the comparison pattern 108 is at least 3μ (micron).

All of the first pair of calibration reticles 110, the second pair of calibration reticles 112, the third pair of calibration reticles 114 and the fourth pair of calibration reticles 116 are disposed around the comparison pattern 108. The first pair of calibration reticles 110 extends along x direction, the second pair of calibration reticles 112 extends along y direction, the third pair of calibration reticles 114 extends along z direction and the fourth pair of calibration reticles 116 extends along w direction.

Remarkably, the lengths in the lithography pattern on the wafer produced by exposing all of the first pair of calibration reticles 110, the second pair of calibration reticles 112, the third pair of calibration reticles 114 and the fourth pair of calibration reticles 116 may be varied with the variation of the focal length. When the lengths of the reticles measured from the lithography pattern are equal to the expected values obtained by exposing the calibration reticles on the wafer, it indicates the used exposure apparatus is be in focus; while the lengths of the reticles measured from the lithography pattern are less than the expected values obtained by exposing the calibration reticles on the wafer, it indicates the used exposure apparatus is be in defocus. The more the defocus, the shorter the lengths in the lithography pattern are.

Another tip to pay attention to is that the chosen width of the calibration reticles must be appropriate, so that the lithography pattern affected by a defocus or other offset parameters related to the focal length is measurable. In more detail, if the width of the calibration reticles is too small, the width of the produced lithography pattern affected by a defocus may be too small to form a complete lithography pattern, which causes a problem for a tester to measure. Contrarily, if the width of the calibration reticles is too large, the width of the produced lithography pattern would be not sensitive enough to the variation of focal length. To compromise the above-described two considerations, that is, to make sure the lithography pattern affected by a defocus or other offset parameters related to the focal length is measurable on the one hand, and to obtain a preferred sensitivity to focal length on the other hand, in an embodiment, the width of the first pair of calibration reticles 110, the second pair of calibration reticles 112, the third pair of calibration reticles 114 and the fourth pair of calibration reticles 116 is, for example, 0.1˜0.2μ (micron). Besides, the reticle number of the first pair of calibration reticles 110, the second pair of calibration reticles 112, the third pair of calibration reticles 114 and the fourth pair of calibration reticles 116 are not specially restricted in the present invention.

Depending on the exposure apparatus with different brands and different models, the pattern configuration on a mask can be varied. For example, the pattern configurations for a 4-multiple mask and a 5-multiple mask are not identical. That is said, the calibration pattern configuration on a calibration mask allows to be varied, depending on the requirement of various apparatuses. Taking the mask 100 in FIG. 1 as exemplary, the calibration patterns indicated by mark □ on the light-transparent substrate 104 are corresponding to an exposure apparatus and have 9 pieces in total, which are arranged on the light-transparent substrate 104 in a transverse interval of h and in a longitudinal interval of v. In other words, all these calibration patterns with mark □ are uniformly arranged on the light-transparent substrate 104 for measuring the overall focal-length across a shot area, which is essential to estimate an apparatus abnormality, such as a large-scale defocus caused by a mask tilt, or other abnormalities. These calibration patterns with mark □ herein are counted as a calibration set, and the calibration pattern number in a calibration set is not specially restricted and allows to be varied depending on the user need.

One more feature of the present invention is that the different calibration patterns corresponding to different apparatuses can be integrated onto a single mask, so that a single mask serves multi exposure apparatuses leading to save cost for fabricating the masks. For example, on the mask 100 another calibration set with mark ◯ corresponding to another exposure apparatus can be disposed too. In more detail, the calibration set with mark ◯ includes, for example, 9 calibration patterns and all the calibration patterns with mark ◯ are uniformly arranged on the light-transparent substrate 104. In fact, the above-described two calibration sets are not limited in the present invention; it can be more than two calibration sets. In this way, the feature of the present invention to integrate a plurality of calibration sets onto a single mask can get double benefits, not only saving cost, but also using a single mask as the same datum for comparing the above-described two or more exposure apparatuses.

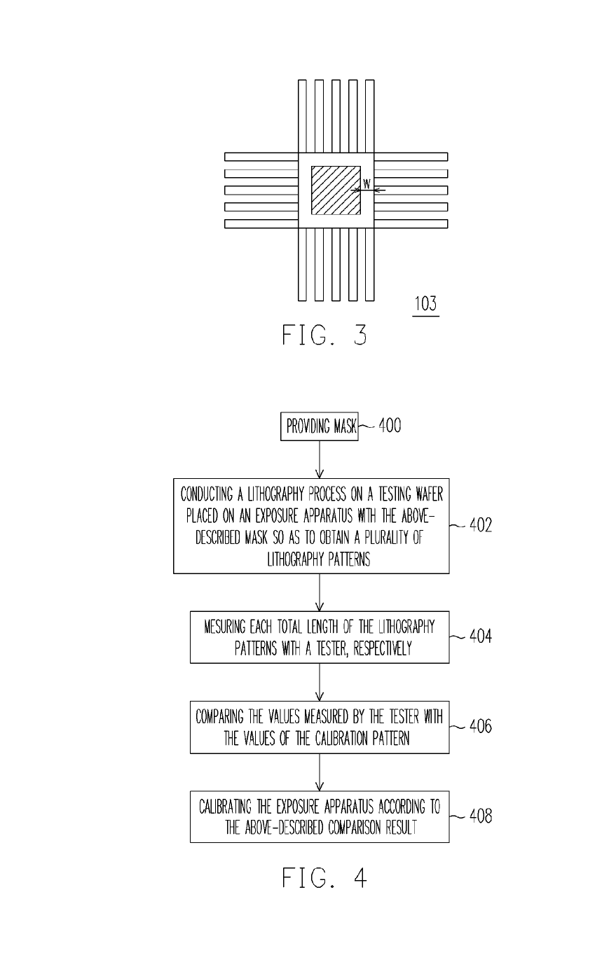

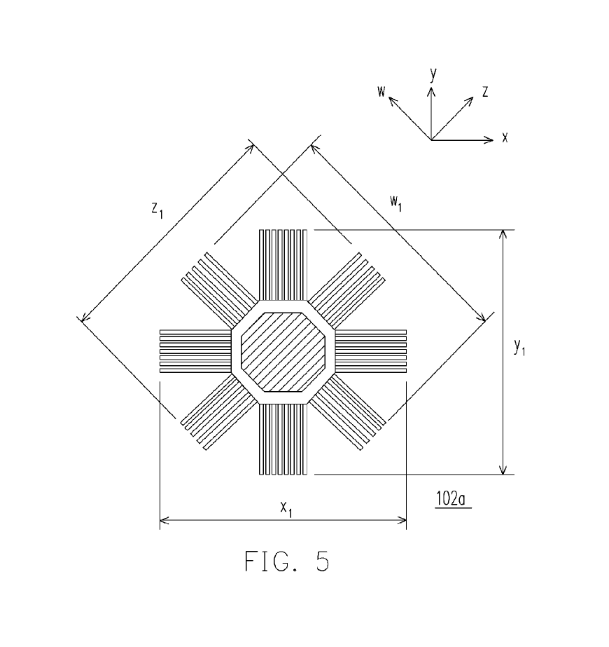

FIG. 4 is a method flowchart for calibrating an exposure apparatus using the above-described mask according to an embodiment of the present invention. Referring to FIG. 4, firstly at step 400, a mask is provided. Wherein, it is, for example, the mask 100 shown in FIG. 1. The mask 100 includes at least a light-transparent substrate 104 and at least two calibration patterns 102 disposed on the light-transparent substrate 104. The calibration patterns 102 are the same as above described and omitted herein for simplicity.

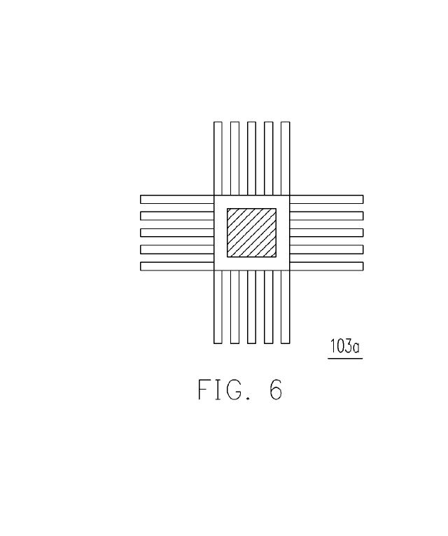

Next at step 402, to get a plurality of corresponded lithography patterns, a lithography process on a tested wafer on an exposure apparatus is conducted using the above-described mask. Wherein, during step 402, a photoresist coating, an exposing and a developing are conducted on the wafer. The obtained lithography pattern 102a in FIG. 5 is corresponding to the calibration pattern 102. In another embodiment, if the mask adapts the calibration pattern 103 shown in FIG. 3, the obtained lithography pattern after the step 402 is 103a in FIG. 6 corresponding to the calibration pattern 103.

Further at step 404, a tester is used to measure the total lengths of the lithography patterns, respectively. FIG. 5 is, for example, a diagram of the lithography pattern 102a obtained by exposing the calibration pattern 102 of FIG. 2. During step 404, a total length x₁ of direction x, a total length y₁ of direction y, a total length z₁ of direction z and a total length w₁ of direction w are measured by the tester. If there is more than one calibration pattern on a mask, a plurality of corresponded calibration patterns would be measured and a plurality of values can be got after the measurement. Wherein, the tester is, for example, an off-line tester, by which the uptime of an exposure apparatus can be enhanced. Besides, the tester is, for example, a microscope, in particular, an electron microscope (EM) provided by, for example, KLA Co. The EM of KLA Co. is used mainly for measuring various geometric dimensions of an integrate circuit (IC).

Furthermore at step 406, the values from the measurements by the tester are compared with the values of the calibration pattern 102 in FIG. 2, which has a total length x₀ of direction x, a total length y₀ of direction y, a total length z₀ of direction z and a total length w₀ and all length are fixed values. After making a comparison between the total length x₀ and the total length x, the defocus extent of the exposure apparatus at direction x can be estimated and further the focal length of the exposure apparatus at direction x can be calibrated based on the defocus extent. Similarly, from a comparisons between the total length y₀ and the total length y, a comparison between the total length z₀ and the total length z and a comparison between the total length w₀ and the total length w, the focal lengths of the exposure apparatus at direction y, direction z and direction w can be calibrated.

Finally at step 408, the above-described results are used to calibrate the exposure apparatus. Wherein, to calibrate the exposure apparatus based on the above-described results, a feedback mechanism is used, so that the obtained comparison results are auto-feedbacked to the exposure apparatus. The feedback mechanism is, for example, an advanced process control (APC).

In addition, in the above-described lithography process, the exposure process on a plurality of shot areas on a tested wafer is allowed. In this way, a plurality of comparison results are produced, from which an average value can be calculated. With the average value to calibrate the exposure apparatus, a less error would be expected.

It can be seen from the above described, the mask and the method for calibrating an exposure apparatus provided by the present invention has at least the following disadvantages.

1. The mask used for calibration provided by the present invention is suitable for various exposure apparatuses. The focal length of each exposure apparatus is consequently able to be compared with a same datum. In this way, there is no need to purchase a plurality of calibration masks corresponding to various exposure apparatuses, respectively, which leads to a significant cost saving.

2. According to the method for calibrating an exposure apparatus provided by the present invention, an off-line tester is used for measuring a wafer, therefore there is no need to bring the tested wafer back to the exposure apparatus for measurements and the uptime of the exposure apparatus and the production capacity thereof is increased. Along with the benefit, the periodical maintenance items and maintenance frequency are reduced.

3. According to the present invention, the focal lengths of various exposure apparatuses can be measured by a single tester. Such an unified measurement mode, based on a same datum and a same measurement method, enables to conclude the focal length relationship between various apparatuses. In particular, when the production capacity of an exposure apparatus is not sufficient, normally other available apparatus can be as a supporting one to take the duty of a supported apparatus. At the moment, the quantitive focal length relationship can serve as the base for judging whether the supporting exposure apparatus qualifies for commutative usage or not.

4. The present invention uses the above-described feedback mechanism to auto-feedback the exposure apparatus, which avoids a possible personal fault by the conventional manual calibration mode.

5. In the above-described lithography process, the exposure on a plurality of shot areas can be conducted, from which a massive measurement results of focal lengths can be obtained.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. A mask, suitable for calibrating an exposure apparatus, comprising:
a light-transparent substrate; and
at least two calibration patterns, disposed on the light-transparent substrate, wherein each calibration pattern comprises:
a recognition pattern, having a symmetricity;
a comparison pattern, disposed around the recognition pattern;
a first pair of calibration reticles, disposed around the comparison pattern and extending along a first direction;
a second pair of calibration reticles, disposed around the comparison pattern and extending along a second direction.

2. The mask as recited in claim 1, wherein the recognition pattern comprises a square and an octagon.

3. The mask as recited in claim 2, wherein the recognition pattern area is at least 100μ² (micron square).

4. The mask as recited in claim 1, wherein the widths of the first pair of calibration reticles and the second pair of calibration reticles are 0.1˜0.2μ (micron).

5. The mask as recited in claim 1, wherein the light-transparent substrate has 9 calibration patterns transversely arranged thereon in a first interval and longitudinally arranged thereon in a second interval.

6. The mask as recited in claim 1, wherein one of the recognition pattern and the comparison pattern is a light-transparent pattern, while another one is a lighttight pattern.

7. The mask as recited in claim 1, wherein the width of the comparison pattern is at least 3μ (micron).

8. A mask, suitable for calibrating an exposure apparatus, comprising:
a light-transparent substrate; and
at least two calibration patterns, disposed on the light-transparent substrate, wherein each calibration pattern comprises:
a recognition pattern, having a symmetricity;
a comparison pattern, disposed around the recognition pattern;
a first pair of calibration reticles, disposed around the comparison pattern and extending along a first direction;
a second pair of calibration reticles, disposed around the comparison pattern and extending along a second direction;
a third pair of calibration reticles, disposed around the comparison pattern and extending along a third direction; and
a fourth pair of calibration reticles, disposed around the comparison pattern and extending along a fourth direction.

9. The mask as recited in claim 8, wherein the recognition pattern comprises a square and an octagon.

10. The mask as recited in claim 9, wherein the recognition pattern area is at least 100μ² (micron square).

11. The mask as recited in claim 8, wherein the widths of the first pair of calibration reticles, the second pair of calibration reticles, the third pair of calibration reticles and the fourth pair of calibration reticles are 0.1˜0.2μ (micron).

12. The mask as recited in claim 8, wherein the light-transparent substrate has 9 calibration patterns transversely arranged thereon in a first interval and longitudinally arranged thereon in a second interval.

13. The mask as recited in claim 8, wherein one of the recognition pattern and the comparison pattern is a light-transparent pattern, while another one is a lighttight pattern.

14. The mask as recited in claim 8, wherein the width of the comparison pattern is at least 3μ (micron).

15. A method for calibrating an exposure apparatus, comprising:
providing a mask, which comprises a light-transparent substrate and at least two calibration patterns on the light-transparent substrate, wherein each calibration pattern comprises:
a recognition pattern, having a symmetricity;
a comparison pattern, disposed around the recognition pattern;
a first pair of calibration reticles, disposed around the comparison pattern and extending along a first direction;
a second pair of calibration reticles, disposed around the comparison pattern and extending along a second direction;
conducting a lithography process on a tested wafer placed on an exposure apparatus by using the mask, so as to obtain a plurality of lithography patterns corresponding to the calibration patterns;
measuring total lengths at the first direction and at the second direction on the lithography patterns using a tester, respectively, so as to obtain a plurality of values;
comparing the values with the values obtained from the total lengths at the first direction and the second direction of the lithography patterns, so as to get a comparison result; and
calibrating the exposure apparatus by using the comparison result.

16. The method for calibrating an exposure apparatus as recited in claim 15, wherein the tester comprises an off-line tester and the tester comprises a microscope.

17. The method for calibrating an exposure apparatus as recited in claim 15, wherein to calibrate the exposure apparatus with the comparison result, a feedback mechanism is used to auto-feedback the comparison result to the exposure apparatus for a calibration.

18. The method for calibrating an exposure apparatus as recited in claim 15, wherein the recognition pattern comprises a square and an octagon.

19. The method for calibrating an exposure apparatus as recited in claim 15, wherein the widths of the first pair of calibration reticles and the second pair of calibration reticles are 0.1˜0.2μ (micron).

20. The method for calibrating an exposure apparatus as recited in claim 15, wherein the widths of the first pair of calibration reticles, the second pair of calibration reticles, the third pair of calibration reticles and the fourth pair of calibration reticles are 0.1˜0.2μ (micron).

21. The method for calibrating an exposure apparatus as recited in claim 15, wherein the light-transparent substrate has 9 calibration patterns transversely arranged thereon in a first interval and longitudinally arranged thereon in a second interval.

22. The method for calibrating an exposure apparatus as recited in claim 15, wherein one of the recognition pattern and the comparison pattern is a light-transparent pattern, while another one is an opaque pattern.

23. The method for calibrating an exposure apparatus as recited in claim 15, wherein the width of the comparison pattern is at least 3μ (micron).

24. A method for calibrating an exposure apparatus, comprising:
providing a mask, which comprises a light-transparent substrate and at least two calibration patterns on the light-transparent substrate, wherein each calibration pattern comprises:
a recognition pattern, having a symmetricity;
a comparison pattern, disposed around the recognition pattern;
a first pair of calibration reticles, disposed around the comparison pattern and extending along a first direction;
a second pair of calibration reticles, disposed around the comparison pattern and extending along a second direction;
a third pair of calibration reticles, disposed around the comparison pattern and extending along a third direction; and
a fourth pair of calibration reticles, disposed around the comparison pattern and extending along a fourth direction;
conducting a lithography process on a tested wafer placed on an exposure apparatus by using the mask, so as to obtain a plurality of lithography patterns corresponding to the calibration patterns;
measuring total lengths at the first direction, at the second direction, at the third direction and at the fourth direction on the lithography patterns using a tester, respectively, so as to obtain a plurality of values;
comparing the values with the values obtained from the total lengths at the first direction, the second direction, the third direction and the fourth direction of the lithography patterns, so as to get a comparison result; and
calibrating the exposure apparatus by using the comparison result.

25. The method for calibrating an exposure apparatus as recited in claim 24, wherein the tester comprises an off-line tester and the tester comprises a microscope.

26. The method for calibrating an exposure apparatus as recited in claim 24, wherein to calibrate the exposure apparatus with the comparison result, a feedback mechanism is used to auto-feedback the comparison result to the exposure apparatus for a calibration.

27. The method for calibrating an exposure apparatus as recited in claim 24, wherein the recognition pattern comprises a square and an octagon.

28. The method for calibrating an exposure apparatus as recited in claim 27, wherein the recognition pattern area is at least 100² (micron square).

29. The method for calibrating an exposure apparatus as recited in claim 24, wherein the light-transparent substrate has 9 calibration patterns transversely arranged thereon in a first interval and longitudinally arranged thereon in a second interval.

30. The method for calibrating an exposure apparatus as recited in claim 24, wherein one of the recognition pattern and the comparison pattern is a light-transparent pattern, while another one is an opaque pattern.

31. The method for calibrating an exposure apparatus as recited in claim 24, wherein the width of the comparison pattern is at least 3μ (micron).
